(19) United States
(12) Patent Application Publication
(10) Pub. No.: US 2024/0030100 A1
(43) Pub. Date: Jan. 25, 2024

(54) METHOD FOR PRODUCING AN ELECTRONIC ASSEMBLY, ELECTRONIC ASSEMBLY, AND MOTOR VEHICLE

(71) Applicant: AUDI AG, Ingolstadt (DE)

(72) Inventor: Daniel RUPPERT, Lenting (DE)

(73) Assignee: AUDI AG, Ingolstadt (DE)

(21) Appl. No.: 18/044,600

(22) PCT Filed: Nov. 22, 2021
(86) PCT No.: PCT/EP2021/082408

§ 371 Date: Mar. 9, 2023

(30) Foreign Application Priority Data
Dec. 16, 2020 (DE) 102020133635.7

(51) Int. Cl. H01L 23/46; H01L 21/48

(52) U.S. Cl. CPC H01L 23/46; H01L 21/4871

(57) ABSTRACT

A method for producing an electronic assembly including providing at least one electrical power module, providing a heat sink having at least one flat depression in at least one side and applying a further copper layer in the flat depression, or providing a heat sink and applying a further copper layer to form a flat depression, or providing a heat sink having at least one flat depression in at least one side, wherein a further copper layer is applied in the depression, arranging the copper layer of the carrier element on the further copper layer, and connecting the copper layer to the further copper layer to fasten the electrical power module on the heat sink.

### FIELD

The invention relates to a method for producing an electronic assembly comprising a heat sink and at least one electrical power module, wherein the electrical power module has an electrical circuit and a plate-shaped carrier element, wherein the electrical circuit is arranged on a first side of the carrier element and the second side of the carrier element has a copper layer in at least some areas. The invention furthermore relates to an electronic assembly and a motor vehicle.

### BACKGROUND

Motor vehicles having an electric drive usually have a traction inverter, via which an electric traction motor is operated. The inverter can, for example, convert direct current from a battery of the motor vehicle into alternating current for operating the electric traction motor or, in recuperation mode, convert alternating current generated by the traction motor into direct current for charging the battery.

The inverter or drive converter usually consists of an intermediate circuit capacitor, a driver circuit, a control circuit, and multiple electrical power modules. During operation of the electric traction motor, these electrical power modules convert a high level of power and therefore have to be cooled. For this purpose, it is known that a power module can have a cooling connection, which is formed, for example, by a cooling fin structure, for example a pin-fin structure, arranged on a lower side of a substrate of the power module. This cooling structure can, for example, be applied directly to a copper layer on a lower side of a carrier element carrying the electrical power module.

The power modules can then be arranged on a heat sink, wherein the cooling structure comes into contact with a coolant such as cooling water. As a result, the semiconductor chips of the power modules can also be cooled via a heat flow through the carrier element and the cooling structure to the cooling medium. Due to the direct contact of the cooling structure with the power module, it is necessary for at least one seal to be arranged between the heat sink and the power module in order to prevent the cooling medium from escaping. The power modules and/or the seals can be fastened directly on the heat sink via fastening means such as screws, clamping blocks, or the like.

It is desirable for a heat sink and at least one electrical power module that it is producible simply as possible and offers a high level of operational reliability. In particular, it is desirable that no leaks occur during operation and that the resulting effort for manufacturing to achieve a high level of operational reliability is as low as possible. Further arrangements for cooling power modules are known from the prior art.

DE 10 2011 076 774 A1 describes an assembly having a carrier on which conductor tracks and electrical components are arranged, and a heat sink which has a thermally conductive connection to the carrier. The carrier has a first solderable layer on a surface facing toward the heat sink and the heat sink has a second solderable layer on a surface facing toward the carrier, wherein the carrier and the heat sink are connected to one another by soldering via the second solderable layer.

DE 10 2017 205 813 A1 describes a method for producing a cooling device. In one application step, a thin copper layer is applied at least in some areas to a joining side of at least one ceramic plate. In a joining step, the respective ceramic plate is connected by material bonding to the upper side of an aluminum body with the supply of heat.

WO 2020/052829 A1 describes a method for producing a power module unit, in which a substrate of a power semiconductor circuit is fastened on the upper side of a heat sink by means of a soldered connection. On a side opposite to the substrate, the heat sink has a plurality of openings, in each of which a cooling fin is fastened.

### SUMMARY

The invention is based on the object of specifying an improved method for producing an electronic assembly which comprises a heat sink and at least one electrical power module.

To achieve this object, it is provided according to the invention in a method of the type mentioned at the outset that it comprises the following steps:
providing the at least one electrical power module,
providing a heat sink having at least one flat depression in at least one side and applying a further copper layer in the flat depression, or providing a heat sink and applying a further copper layer to form a flat depression, or providing a heat sink having at least one flat depression in at least one side, wherein a further copper layer is applied in the recess,
arranging the copper layer of the carrier element on the further copper layer,
connecting the copper layer to the further copper layer to fasten the electrical power module to the heat sink.

In order to enable the electrical power module to be fastened during the production of the electronic assembly and to efficiently cool the electrical power module during operation of the electronic assembly, a heat sink is used which has at least one further copper layer arranged in a flat depression. For this purpose, a heat sink can be provided during production, which has a flat depression on at least one side, wherein the further copper layer is applied in the depression.

Alternatively, a heat sink can be provided, to which the additional copper layer is applied, forming the flat depression. The further copper layer is thus applied in such a way that during the application a depression forms in the heat sink, in which the further copper layer is arranged.

A third possibility is to provide a heat sink which already has the at least one flat depression and the copper layer applied in the flat depression. Such a heat sink can, for example, have been produced according to one of the two above-mentioned options.

The further copper layer is applied in such a way that the further copper layer is fastened to the heat sink, in particular permanently and stably. The further copper layer arranged in the planar depression of the heat sink has the advantage that it can be used to fasten the electrical power module. For this purpose, after the copper layer on the second side of the carrier element of the power module is arranged on the further copper layer, the copper layer is connected to the further copper layer, so that the electrical power module is fastened on the heat sink via the copper layers that are now connected. The further copper layer preferably has an area which corresponds at least to the area of the copper layer of the carrier element, so that the connection having the largest possible area can be produced between the power module and the heat sink.

The plate-shaped carrier element can be, for example, a direct copper bonded substrate (DCB substrate), in which the electrical circuit, which comprises, for example, one or more power semiconductor components and copper conductor tracks, is arranged on a first side of an insulating substrate. The copper layer arranged on the second side can be used to fasten the power module on the further copper layer of the heat sink.

By fastening the power module on the heat sink via the connection of the copper layer to the further copper layer, further fastening means such as screws and/or clamping blocks can advantageously be dispensed with. As a result, when arranging the copper layer of the carrier element on the further copper layer or when arranging the electrical power module on the heat sink, complex positioning devices for the screw connection and/or the arrangement of the clamping blocks can moreover be dispensed with, so that the arranging or positioning of the electrical power modules in relation to the heat sink is simplified. In this case, in particular carrying out the production of the electronic assembly in an automated manner can be simplified, due to which both the production costs can be reduced and the reliability of the automated production can be improved.

The use of the or a further copper layer on the at least one side of the heat sink also makes it possible for heat generated in the electrical circuit of the power module during operation of the electronic assembly to be transported away via the heat sink. Openings in the heat sink, which effectuate cooling of the copper layer on the second side of the carrier element and/or a cooling structure arranged on the copper layer by direct contact with a coolant, can thus advantageously be dispensed with. This further simplifies the production of the electronic assembly, since the complex arrangement of sealing elements for sealing between the heat sink and the power module can advantageously be dispensed with.

In addition, further process steps such as leak tests and/or the design of different sealing interfaces for differently designed electrical power modules are also omitted. Checking screw connections, for example as part of torque monitoring, can also advantageously be dispensed with because the electrical power modules are fastened via the copper layers. Furthermore, the handling of the heat sink is facilitated, in particular during the arrangement of the electrical power module or the copper layer of the carrier element and/or during the connection of the copper layers. Furthermore, it is achieved that the further copper layer is only arranged at the position of the heat sink at which the copper of the further copper layer is required for heat dissipation from the power module into the heat sink.

Applying the further copper layer to the heat sink also has the advantage that the high thermal conductivity of the further copper layer can be used to dissipate heat from the electrical power module. Improved heat dissipation from the power module into the heat sink is thus achieved. The direct fastening of the power module on the heat sink means that the high thermal conductivity and the high heat capacity of the copper layer and the additional copper layer can be utilized without the entire heat sink having to be manufactured from copper. This enables the use of heat sinks made from lighter and/or less expensive materials.

The heat sink can in particular consist of aluminum, so that it is lightweight and can be produced inexpensively. The heat sink can be designed for passive cooling or it can comprise at least one cooling channel which extends inside the heat sink and through which a coolant can be guided, which dissipates the heat generated in the at least one power module and conducted to the heat sink.

The method according to the invention advantageously reduces the production costs of a heat sink having a cooling channel in particular, since openings or recesses in which the power modules are arranged for cooling can advantageously be dispensed with. The production costs of the electronic assembly can also be further reduced by dispensing with the seals, which is thus made possible, and by the fastening, which does not require fastening elements such as screws and/or clamping blocks.

This further shortens the production time of the electronic assembly and the reduced number of steps advantageously facilitates automated manufacturing of the electronic assembly. Furthermore, the installation space and the weight of the electronic assembly are reduced, since multiple power modules can be placed closer together on the heat sink, since no screw connections and/or clamping blocks have to be arranged between the power modules. By dispensing with seals between the power modules and the heat sink, the thermal robustness of the overall system is furthermore increased, due to which the service life of the electronic assembly can be advantageously increased.

In a preferred embodiment of the invention it can be provided that the copper layer is connected to the further copper layer by means of sintering and/or by means of soldering. The copper layer can be connected to the further copper layer, for example by means of a copper sintering process. For this purpose, pressure can be exerted on the power module and/or the heat sink and the electronic assembly can be heated to a temperature between 200° C. and 400° C., in particular to 300° C.

It is possible that at least one additional material, for example, copper particles for sintering and/or a solder for soldering is arranged between the copper layer and the further copper layer. By sintering or soldering the copper layer with the further copper layer, stable fastening of the electrical power module on the heat sink is achieved, so that further fastening elements such as screws or the like can advantageously be dispensed with.

According to the invention, it can be provided that the further copper layer is applied in the depression by means of a roll-plating process and/or that the further copper layer is applied by means of a roll-plating process to form the depression. The additional copper layer can have, for example, a thickness between 10 μm and 200 μm, in particular 100 μm, and can be in the form of a copper foil or copper sheet. The roll-plating process can be carried out under high roll pressure, so that during the application of the copper layer, the flat depression, in which the copper layer is subsequently accommodated, can also be formed if the heat sink used does not already have one.

Alternatively, the further copper layer can be applied in an already existing flat depression of the heat sink. For example, with a heat sink made of aluminum, a copper-aluminum material composite can be produced by the roll-plating process. In this way, the properties of the aluminum cooler, in particular with regard to its thermal conductivity and/or its heat capacity, can be improved in some areas by the further copper layer.

According to the invention, it can be provided that a further copper layer is used, which after application is at least essentially flush with the side of the heat sink and/or which completely fills the depression after application, or that a heat sink with a further copper layer, which is at least substantially flush with the side of the heat sink and/or which completely fills the recess, is provided. A copper layer that terminates flush with the side of the heat sink has a thickness that corresponds to the depth of the flat depression. A further copper layer that completely fills the planar recess lies against the side walls of the depression on all sides of the depression, so that no air gaps are formed between the sides of the further copper layer and the heat sink.

The further copper layer can in particular be applied in such a way that it completely fills an already existing flat depression and/or that it terminates flush with the side of the heat sink. It is also possible that a further copper layer is used, which is essentially flush with the side of the heat sink and/or completely fills the depression if the depression is formed during the application of the copper layer. Correspondingly, a heat sink can also be provided which already has a further copper layer which terminates essentially flush with the side of the heat sink and/or completely fills the depression.

The flush termination with the side of the heat sink can additionally simplify the arrangement of the power module or the copper layer on the further copper layer, since the side of the heat sink on which the at least one further copper layer is arranged and on which the at least one power module is fastened is at least essentially flat. By completely filling the depression with the further copper layer, heat transfer between the further copper layer and the heat sink and thus also between the copper layer on the second side of the carrier element of the power module and the heat sink can be improved.

In one preferred embodiment of the invention, it can be provided that an electrical power module is provided, the electrical circuit of which is surrounded by a potting material. The use of at least one power module, the electrical circuit of which is already surrounded by a potting material, facilitates the handling of the electrical power module during the production of the electronic assembly. Unintentional impairments of the electrical circuit, in particular of electrical components and/or electrical connections of the electrical circuit, can thus advantageously be avoided.

Arranging the power module or the copper layer of the carrier element on the further copper layer is also simplified if the electrical circuit arranged on the first side of the carrier element and/or the carrier element are surrounded by a potting material. The potting material surrounds the electrical circuit in such a way that the second side of the carrier element, on which the copper layer is located, is not surrounded by the potting material, so that it is exposed and can be connected to the further copper layer on the heat sink. If the copper layer is connected to the further copper layer by means of a soldering process and/or a sintering process, a potting material is selected that is stable at the temperatures and/or pressures required for sintering or soldering, so that the potting material is not deformed or degraded when fastening the power module or when connecting the copper layers.

In a preferred embodiment of the invention, it can be provided that a heat sink is used, in the interior of which extends a cooling channel through which a cooling medium can flow, wherein at least one cooling fin projecting into the cooling channel is formed opposite to the depression. The cooling fin or the cooling fins can in particular be formed in one piece with the side of the heat sink having the depression.

In order to simplify the production of the heat sink, it can be provided that a heat sink formed from two partial elements is used, so that the production of the internal cooling channel and the cooling fins can be simplified. In this case, at least one partial element of the heat sink can have at least two connections corresponding to the cooling channel, so that the heat sink can be connected, for example, to lines for the supply and removal of cooling water or another cooling medium.

The heat transfer between the further copper layer and thus between the power module and the cooling medium is further improved by the cooling fin arranged opposite to the depression, since a larger contact surface is produced between the heat sink and the cooling medium. For example, a plurality of cooling fins, for example a pin-fin structure, can be arranged opposite to the depression, which in particular extends at least over an area corresponding to the entire area of the indentation. The at least one cooling fin can in particular be formed in one piece with the heat sink or a partial element of the heat sink. This allows the cooler to be made of aluminum, for example, by means of extrusion.

According to the invention, it can be provided that multiple electrical power modules are fastened on a common further copper layer or that the at least one side of the heat sink has multiple depressions, in each of which a further copper layer is applied, wherein multiple power modules are each fastened on one of the multiple further copper layers. This allows multiple power modules to be fastened on the heat sink and cooled via the heat sink. It is possible for the power modules to be all arranged on the same side of the heat sink, or for one or more further copper layers to be arranged in each case in a flat depression on more than one side of the heat sink.

In one preferred embodiment of the invention, it can be provided that an electrical power module designed as a half-bridge is used. In particular, three electrical power modules can be fastened on the heat sink, wherein the power modules can in particular be interconnected to form an inverter or a traction converter. For this purpose, further components of an inverter, for example an intermediate circuit capacitor, an activation circuit for the power modules, and electrical connecting means such as busbars or the like, can be connected to the power modules and/or arranged on the heat sink.

It is provided for an electronic assembly according to the invention that it comprises a heat sink and at least one electrical power module, wherein the heat sink has at least one side with at least one flat depression, wherein the electrical power module has an electrical circuit and a plate-shaped carrier element, wherein the electrical circuit is arranged on the first side of the carrier element and the electrical power module is fastened on the heat sink via a copper ply arranged between the second side of the carrier element and the heat sink, wherein the copper ply is arranged at least partially in the depression.

The electronic assembly can be produced in particular according to the method according to the invention. During production of the electronic assembly by means of the method according to the invention, the copper ply, which is arranged between the second side of the carrier element and the heat sink and which is at least partially arranged in the depression, is formed by the copper layer on the second side of the carrier element and by the further copper layer applied in the depression. In this case, the copper ply is formed by connecting the copper layer to the further copper layer during the production of the electronic assembly.

According to the invention, it can be provided that the copper ply is formed from a copper layer and a further copper layer, which are connected by means of sintering and/or by means of soldering. In addition to the copper layer and the further copper layer, the copper ply can optionally comprise material introduced between the copper layer and the additional copper layer for sintering and/or soldering, for example sintered particles or a solder.

In a preferred embodiment of the invention, it can be provided that the copper layer is at least essentially flush with the side of the heat sink and/or that the additional copper layer fills the depression. The copper ply, which comprises the copper layer and the further copper layer, can in particular protrude from the depression by a height which corresponds to the thickness of the copper layer.

According to the invention, it can be provided that a cooling channel through which a cooling medium can flow extends in the interior of the heat sink, wherein at least one cooling fin projecting into the cooling channel is formed opposite to the depression. This improves the cooling of the at least one power module due to the enlarged contact area between the cooling medium and the heat sink, in particular when heat is transported via the copper ply arranged in the depression.

In one preferred embodiment of the invention, it can be provided that multiple electrical power modules are fastened on a common copper ply or that the side of the heat sink has multiple depressions in each of which a copper ply is applied, wherein multiple power modules are each fastened on one of the multiple copper plies. In particular, the electronic assembly can have three power modules which are fastened in a common copper ply or which are each fastened to one of three copper plies which are arranged in three flat depressions of the heat sink. The three flat depressions can in particular be located on the same side of the heat sink, so that the power modules can be arranged adjacent to one another on the side of the heat sink.

According to the invention, the electrical power module can be a half-bridge. An inverter can be formed in particular by three electrical power modules of an electronic assembly. For this purpose, the electronic assembly can comprise further electrical components, which can be arranged separately from the heat sink. It is also possible for the further components to be fastened arranged on the heat sink on the same side as the electrical power modules or on a different side of the heat sink. For example, an intermediate circuit capacitor, an activation circuit for the power modules, and/or connecting means such as busbars can be provided as further components.

Is provided for a motor vehicle according to the invention that it comprises at least one electronic assembly according to the invention. The electronic assembly can in particular represent a traction inverter or a component part of a traction inverter. The traction inverter can be connected to an energy storage device of the motor vehicle and to an electric traction motor of the motor vehicle. The heat sink can be connected to a cooling medium circuit of the motor vehicle, so that efficient cooling via the heat sink is enabled.

### BRIEF DESCRIPTION OF THE FIGURES

Further advantages and details of the invention follow from the exemplary embodiments described below and from the drawings. In the schematic representations of the figures:

FIG. 1 shows an exemplary embodiment of a motor vehicle according to the invention,

FIG. 2 shows an exemplary embodiment of an electronic assembly according to the invention,

FIG. 3 shows a top view of a heat sink of the electronic assembly,

FIG. 4 shows a top view of the electronic assembly, and

FIG. 5 shows a flow chart of an exemplary embodiment of a method according to the invention for producing an electronic assembly.

### DETAILED DESCRIPTION

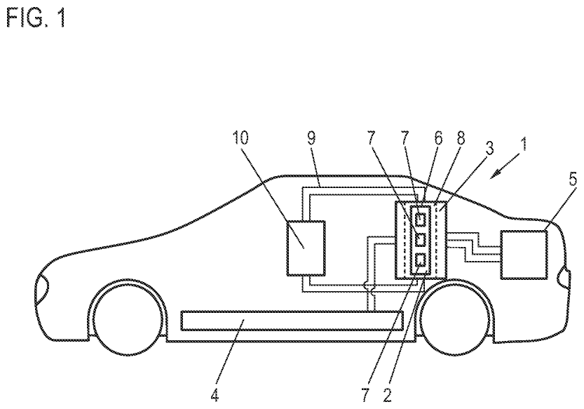

FIG. 1 shows an exemplary embodiment of a motor vehicle 1. The motor vehicle 1 comprises an electronic assembly 2 which forms part of a traction inverter 3 of the motor vehicle 1. The traction inverter 3 or drive converter is used to convert a direct current emitted by a traction battery 4 of the motor vehicle 1 into an alternating current for operating a traction motor 5 of the motor vehicle 1. The traction inverter 3 can also be used to convert an alternating current generated by the traction motor 5 into a direct current for charging the traction battery 4.

The electronic assembly 2 comprises a heat sink 6 and three electrical power modules 7 which are fastened on the heat sink 6. The power modules 7 are each designed as a half-bridge, so that the traction inverter 3 is embodied, for example, as a three-phase bridge inverter by the three power modules 7. In addition to the power modules 7, the traction inverter 3 can also comprise further electrical components which are electrically connected to the power modules 7 and which can be arranged on the heat sink 6. These components can be, for example, an intermediate circuit capacitor, a control circuit for activating the power modules 7 designed as half-bridges, and/or electrical connecting means such as busbars or the like.

The heat sink 6 can be a passive heat sink or it can include a cooling channel 8 as will be described in more detail hereinafter. The cooling channel 8 can be connected to a cooling circuit of the motor vehicle 1 via two lines 9 in order to allow a cooling medium of the cooling circuit to circulate through the cooling channel 8 in a driving mode of the motor vehicle 1 and thus in particular to cool the power modules 7 of the electronic assembly 2.

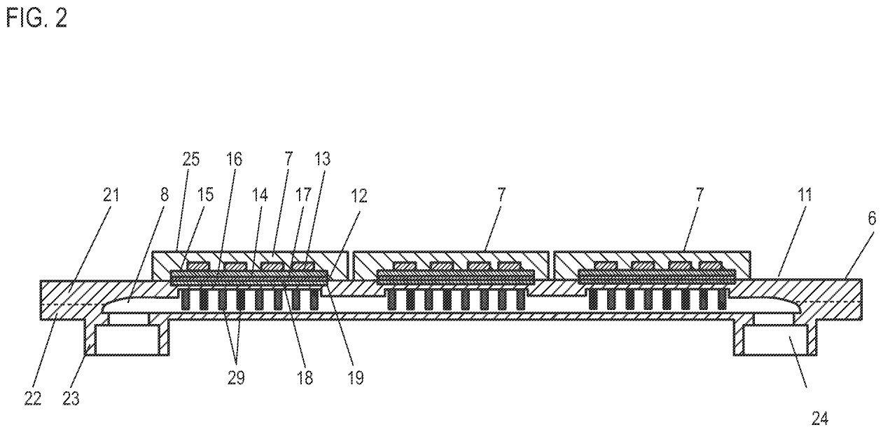

A sectional side view of the electronic assembly 2 is shown in FIG. 2. The heat sink 6 comprises a side 11 having three flat depressions 12. The power modules 7 each comprise an electrical circuit 13 and a plate-shaped carrier element 14, wherein the electrical circuit 13 is arranged on a first side 15 of the carrier element 14. A copper layer 17 is arranged on the opposite second side 16 of the carrier element 14. A copper ply 19 is formed from this copper layer 17 and a further copper layer 18 which is arranged in the recess 12 of the heat sink 6. The power module 7 is fastened on the heat sink 6 via the copper ply 19.

The copper layer 17, which forms a DCB substrate, for example, with the plate-shaped carrier element 15 and/or conductor tracks of the electrical circuit 13 arranged on the first side 14, is connected to the further copper layer 18, for example, by means of sintering and/or by means of soldering. The further copper layer 18 completely fills the flat depression 12 and terminates flush with a surface of the side 11 of the heat sink 6.

By means of the copper ply 19 formed from the copper layer 17 and the further copper layer 18, heat generated during operation of the power modules 7 can be passed on to the heat sink and can be emitted there to a cooling medium circulating in the cooling channel 8 extending in the interior of the heat sink 6. In order to facilitate the heat transfer to the cooling medium in the cooling channel 8, multiple cooling fins 20, which form a pin-fin structure, for example, are provided opposite to the depression 12.

The heat sink 6 consists of aluminum and is formed from two partial elements 21, 22. The cooling fins 20 are formed in one piece with the upper partial element 21. Two connections 23, 24 are arranged on the lower partial element 22, which communicate with the cooling channel 8 and enable the cooling element 6 to be connected to the cooling circuit 10 of the motor vehicle 1, for example. The two partial elements 21, 22 of the heat sink 6 can be manufactured, for example, by means of extrusion and can then be welded together to form the heat sink 6. The cooling channel 8 is delimited by the partial elements 21, 22, wherein a cooling medium of the cooling circuit 10 can be supplied to or removed from the cooling channel 8 via the connections 23, 24.

Good heat transfer between the power module 7 and the coolant circulating in the cooling channel 8 is enabled by the further copper layer 18 accommodated in the depression. The copper layer 18 can have a thickness of between 10 μm and 200 μm, in particular a thickness of 100 μm. In addition to good heat dissipation, the copper ply 19 or the copper layer 17 and the further copper layer 18 are used to fasten the respective power module 7 on the heat sink 6.

This makes it possible to dispense with further fastening means such as screws, clamping blocks, or the like and allows the power modules 7 to be positioned closely adjacent to one another on the side 11. The further copper layer 18 accommodated in the depression 12 advantageously enables heat removal to be achieved in the cooling channel 8 without having to arrange sealing elements between the power module 7 and the heat sink 6 for this purpose, since the heat sink 6 is designed to be completely closed with the exception of the connections 23, 24. In this way, the number of seals required can be reduced to two seals arranged on the connections 23, 24.

The electrical circuits 13 and the carrier elements 15 of the electrical power modules 7 are each surrounded by a potting material 25 which protects the electrical circuit 13 in particular.

It is possible for the depressions 12 to be designed as a depression in which a common further copper layer for fastening the three power modules 7 is applied.

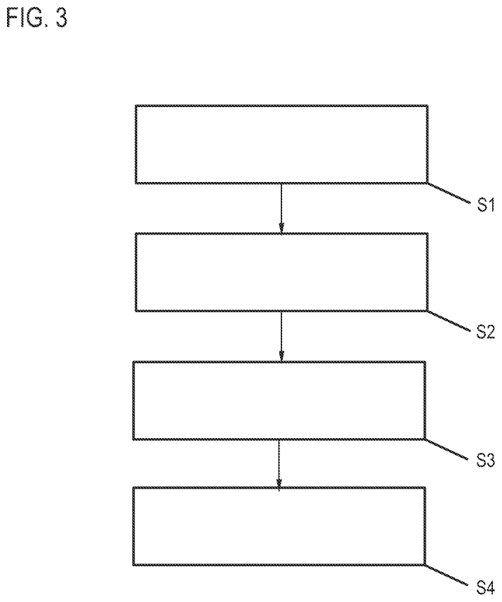

FIG. 3 shows a flow chart of an exemplary embodiment of a method for producing the electronic assembly 2. The electronic assembly shown in FIG. 2, for example, can be produced by means of this method.

The method comprises a first step S1, in which one or more electrical power modules 7 are provided. The electrical power modules 7 each comprise the plate-shaped carrier element 15, on the first side 14 of which the electrical circuit 8 is arranged. The copper layer 17 is arranged on the second side 16 of the carrier element 15. The power module 7 preferably furthermore comprises the potting material 25, which in particular protects the electrical circuit 13 of the power module 7 and simplifies the handling of the power module 7 during the production of the electronic assembly 2.

In a second step S2 of the method, the heat sink 6 having the flat depression 12 is provided and the further copper layer 18 is applied in the flat depression 12. In this case, a heat sink 6 can be used in particular which is already composed of the two partial elements 21, 22 and in the interior of which the cooling channel 8 and/or the cooling fins 20 are already formed. The further copper layer 18 is applied to the flat depression 12, for example, by means of a roll-plating method, wherein a copper foil or copper sheet is arranged on the heat sink 6 in the flat depression 12 to form the further copper layer. The further copper layer 18 is connected to the heat sink 6 made of aluminum by the roll-plating process, wherein a copper-aluminium hybrid material is formed.

Alternatively thereto, it is possible that in step S2 the heat sink 6 is provided and the further copper layer 18 is applied to the side 11 of the heat sink 6 by means of a roll-plating method, for example, forming the flat depression 12. In this case, for example, the flat depression 12 can be produced by roll-plating a further copper layer designed as copper foil or copper sheet into the side 11 of the heat sink and the further copper layer 18 can be firmly and permanently connected to the heat sink. The further copper layer 18 can then be wholly or partially accommodated in the planar depression 12, for example depending on the rolling pressure used.

In a further alternative, a heat sink 6 can be provided in step S2, which already comprises the flat depression 12 and the further copper layer 18 arranged in the flat depression 12. The heat sink 6 can, for example, have been produced according to one of the alternatives described above.

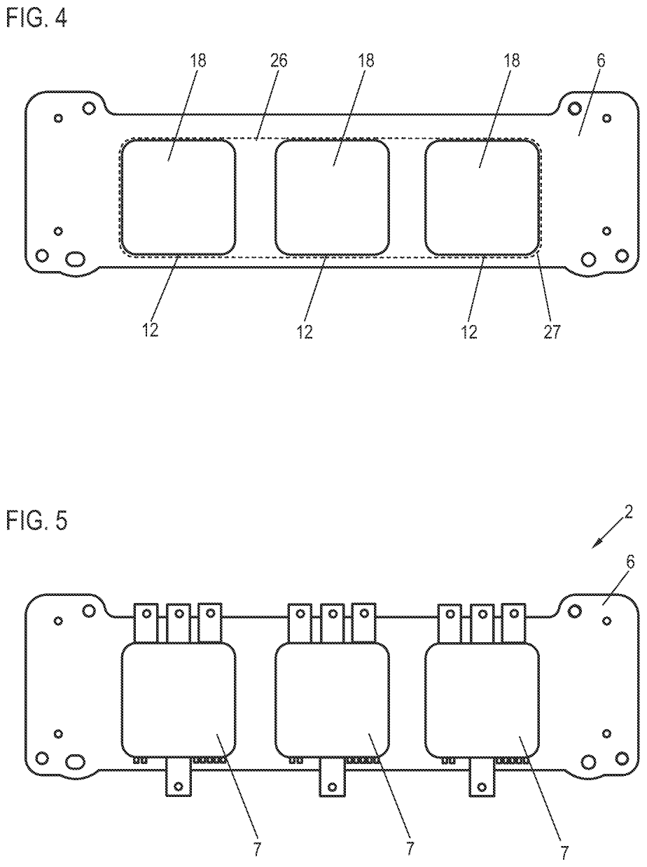

FIG. 4 shows a top view of the heat sink 6, which has three further copper layers 18, each of which is arranged in a flat depression 12. The flat depressions 12 or the further copper layers applied in the flat depressions 12 each have an at least essentially square shape and rounded corners. If three further copper layers 18 are used, the power modules 7 can each be fastened on one of the further copper layers 18.

Alternatively thereto, it is possible for a single further copper layer 26 to be arranged in a depression 27 which, for example, has a rectangular shape, as shown in dashed lines. If the single further copper layer 26 is used, the power modules 7 can be fastened jointly on the single further copper layer 26.

To fasten the power modules 7, the copper layers 17 of the carrier elements 14 are arranged on the further copper layers 18 in step S3. In particular, the copper layers 17 are arranged in such a way that they overlap as completely as possible with the further copper layers 18 or the common further copper layer 26. It is possible for a material to be applied between the copper layer 17 and the further copper layer 18 before the arrangement, which material simplifies the subsequent fastening of the power modules 7 on the heat sink 8.

In step S4, the electrical power modules 7 are fastened on the heat sink 8 by connecting the copper layers 17 to the one or more further copper layers 18 or 26. The connection can be made by means of a sintering process and/or by means of soldering. For this purpose, the components of the electronic assembly 2 can be heated, for example to a temperature between 200° C. and 400° C., in particular to a temperature of approximately 300° C. By applying pressure to the power module 7 and the heat sink 6, a connection of the copper layer 17 to the further copper layer 18 can take place by means of a copper sintering process. Alternatively thereto, it is possible to connect the copper layers 17 to the one or more further copper layers 18 by soldering. The use of power modules 7, the electrical circuit 8 of which is surrounded by the potting material 26, facilitates the handling of the power modules 7, in particular in this process step.

In this case, a potting material is used which has such a temperature stability that it remains dimensionally stable and is not impaired during the fastening by means of sintering or soldering. The use of power modules that have already been potted has the advantage that the power modules 7 can be arranged on the heat sink and pressure can be applied if necessary during sintering and/or soldering without the disadvantage of the power modules 7 being negatively affected, in particular their electrical circuits 13.

The electronic assembly 2 is shown in FIG. 5, wherein the power modules 7 are arranged on the heat sink 6. The power modules 7 or their connections can then be connected to further components of the traction inverter 3.

In all of the exemplary embodiments, it is possible for at least one further copper layer 18, 26 to be applied to more than one side of the heat sink 6, in each case in a flat depression 12, wherein one or more electrical power modules 7 are each arranged on the one or more further copper layers 18, 26.

1-15. (canceled)

16. A method for producing an electronic assembly comprising a heat sink and at least one electrical power module, wherein the electrical power module has an electrical circuit and a plate-shaped carrier element, wherein the electrical circuit is arranged on a first side of the carrier element and the second side of the carrier element has a copper layer in at least some areas, the method comprising:
providing the at least one electrical power module,
providing a heat sink having at least one flat depression in at least one side and applying a further copper layer in the flat depression, or providing a heat sink and applying a further copper layer to form a flat depression, or providing a heat sink having at least one flat depression in at least one side, wherein a further copper layer is applied in the depression, arranging the copper layer of the carrier element on the further copper layer, and
connecting the copper layer to the further copper layer to fasten the electrical power module on the heat sink.

17. The method as claimed in claim 16, wherein the copper layer is connected to the further copper layer by sintering and/or by soldering.

18. The method as claimed in claim 16, wherein the further copper layer is applied in the depression by a roll-plating process and/or the further copper layer is applied by a roll-plating process to form the depression.

19. The method as claimed in claim 16, wherein a third copper layer is used, which after application is at least essentially flush with the side of the heat sink and/or which completely fills the depression after application, or a heat sink having the third copper layer, which is at least substantially flush with the side of the heat sink and/or which completely fills the depression, is provided.

20. The method as claimed in claim 16, wherein an electrical power module is provided, the electrical circuit of which is surrounded by a potting material.

21. The method as claimed in claim 16, wherein another heat sink is used, in the interior of which extends a cooling channel through which a cooling medium can flow, wherein at least one cooling fin projecting into the cooling channel is formed opposite to the depression.

22. The method as claimed in claim 16, wherein multiple electrical power modules are fastened on a common further copper layer or the side of the heat sink has multiple depressions, in each of which a third copper layer is applied, wherein multiple power modules are each fastened on one of the multiple third copper layers.

23. The method as claimed in claim 16, wherein the electrical power module is designed as a half-bridge.

24. An electronic assembly comprising a heat sink and at least one electrical power module, wherein the heat sink has at least one side with at least one flat depression, wherein the electrical power module has an electrical circuit and a plate-shaped carrier element, wherein the electrical circuit is arranged on a first side of the carrier element and the electrical power module is fastened on the heat sink via a copper ply arranged between the second side of the carrier element and the heat sink, wherein the copper ply is arranged at least partially in the depression.

25. The electronic assembly as claimed in claim 24, wherein the copper ply is formed from a copper layer and a further copper layer, which are connected by sintering and/or by soldering.

26. The electronic assembly as claimed in claim 25, wherein the further copper layer is at least essentially flush with the side of the heat sink and/or the further copper layer completely fills the depression.

27. The electronic assembly as claimed in claim 24, wherein a cooling channel extends in the interior of the heat sink through which channel a cooling medium can flow, wherein at least one cooling fin projecting into the cooling channel is formed opposite to the depression.

28. The electronic assembly as claimed in claim 24, wherein multiple electrical power modules are fastened on a common copper ply or the side of the heat sink has multiple depressions in each of which a copper ply is applied, wherein multiple power modules are each fastened on one of the multiple copper plies.

29. The electronic assembly as claimed in claim 24, wherein the electrical power module is a half-bridge.

30. A motor vehicle comprising at least one electronic assembly as claimed in claim 24.

31. The method as claimed in claim 17, wherein the further copper layer is applied in the depression by a roll-plating process and/or the further copper layer is applied by a roll-plating process to form the depression.

32. The method as claimed in claim 17, wherein a third copper layer is used, which after application is at least essentially flush with the side of the heat sink and/or which completely fills the depression after application, or a heat sink having the third copper layer, which is at least substantially flush with the side of the heat sink and/or which completely fills the depression, is provided.

33. The method as claimed in claim 18, wherein a third copper layer is used, which after application is at least essentially flush with the side of the heat sink and/or which completely fills the depression after application, or a heat sink having the third copper layer, which is at least substantially flush with the side of the heat sink and/or which completely fills the depression, is provided.

34. The method as claimed in claim 17, wherein an electrical power module is provided, the electrical circuit of which is surrounded by a potting material.

35. The method as claimed in claim 18, wherein an electrical power module is provided, the electrical circuit of which is surrounded by a potting material.
